(19) United States
(12) Patent Application Publication
(10) Pub. No.: US 2025/0374795 A1
(43) Pub. Date: Dec. 4, 2025

(54) TRANSPARENT DISPLAY DEVICE

(71) Applicant: DARWIN PRECISIONS CORPORATION, Hsinchu County (TW)

(72) Inventors: CHANG-HSIN WU, Hsinchu County (TW); YI-JYI PAN, Hsinchu County (TW); YU-MING HUANG, Hsinchu County (TW)

(21) Appl. No.: 18/764,376

(22) Filed: Jul. 5, 2024

(30) Foreign Application Priority Data
Jun. 4, 2024 (TW) 113120687

(51) Int. Cl. H10K 59/50

(52) U.S. Cl. CPC H10K 59/50

(57) ABSTRACT

A transparent display device includes a transparent display module and a photochromic film. The transparent display module has a first side and a second side opposite to the first side, wherein the first side serves as the display side. The photochromic film is disposed on one of the first side and the second side of the transparent display module. This transparent display device has the effect of improving the display contrast, making the display content clearly visible and allowing outdoor scenes to be seen through, and has the advantage of energy saving.

### CROSS-REFERENCE TO RELATED APPLICATION

This application claims the priority benefit of Taiwan Application No. 113120687, filed on Jun. 4, 2024. The entirety of the above-mentioned patent application is hereby incorporated by reference herein and made a part of this specification.

### FIELD OF THE INVENTION

The invention relates to the field of display technologies, and more particularly to a transparent display device.

### BACKGROUND OF THE INVENTION

A transparent display panel is characterized with transparency, thinness, lightweight, and the like, which can improve human-machine interaction and enable information dissemination to be presented in a more intuitive way. The transparent display panel usually requires a clear display and the ability to be clearly seen through to see an object or background behind the transparent display panel at the same time. However, reflected light and stray light caused by an ambient light source have a significant impact on color rendering effect of the transparent display panel. In particular, when there is sufficient sunlight outdoors, contrast between light and dark is poor, which does not facilitate color presentation of an image and causes displayed content to be seen not clearly, and a good viewing effect can be obtained only under dark background light. Therefore, the transparent display panel is not well used outdoors.

### SUMMARY OF THE INVENTION

The invention provides a transparent display device, which has the effect of improving the display contrast, making the display content clearly visible and allowing outdoor scenes to be seen through, and has the advantage of energy saving.

The transparent display device provided in the present invention includes a transparent display module and a photochromic film. The transparent display module has a first side and a second side opposite to the first side, wherein the first side serves as a display side. The photochromic film includes a photochromic substrate and an adhesive layer. The adhesive layer is disposed on one side of the photochromic substrate, and the photochromic film is disposed on one of the first side and the second side of the transparent display module.

In an embodiment of the present invention, the photochromic substrate is suitable for reversibly changing a color when illuminated by an ultraviolet light source and returning to an original state when the ultraviolet light source is removed.

In an embodiment of the present invention, the adhesive layer is disposed between the transparent display module and the photochromic substrate.

In an embodiment of the present invention, the adhesive layer is a transparent adhesive.

In an embodiment of the present invention, the adhesive layer includes a transparent adhesive and multiple photochromic particles. The photochromic particles are distributed on the transparent adhesive, and the photochromic particles are suitable for reversibly changing a color when illuminated by an ultraviolet light source and returning to an original state when the ultraviolet light source is removed.

In an embodiment of the present invention, the photochromic film further includes a release film disposed on one side of the adhesive layer away from the photochromic substrate, so that the adhesive layer is disposed between the release film and the photochromic substrate.

In an embodiment of the present invention, the photochromic film further includes a transparent reinforcing plate disposed on one side of the adhesive layer away from the photochromic substrate, so that the adhesive layer is disposed between the transparent reinforcing plate and the photochromic substrate.

In an embodiment of the present invention, the transparent display device further includes a frame, suitable for framing the release film/transparent reinforcing plate, the adhesive layer, and the photochromic substrate. The release film/transparent reinforcing plate, the adhesive layer, and the photochromic substrate are stacked on each other.

In an embodiment of the present invention, the photochromic substrate is located between the transparent display module and the adhesive layer.

In an embodiment of the present invention, the transparent display device further includes a frame, suitable for framing the photochromic film and the transparent display module.

In an embodiment of the present invention, the photochromic film is stacked on the transparent display module.

In an embodiment of the present invention, there is a distance between the photochromic film and the transparent display module.

In an embodiment of the present invention, a material of the photochromic substrate includes polyethylene terephthalate (PET) or polycarbonate (PC).

In an embodiment of the present invention, the transparent display module includes an organic light-emitting diode display panel.

In an embodiment of the present invention, the transparent display module includes a display glass and a projection unit. Two opposite sides of the display glass serve as the first side and the second side respectively. The projection unit is disposed on one of the first side and the second side and is suitable for projecting an image onto the display glass.

In the present invention, the photochromic film is attached to or disposed on one side of the transparent display module, and the brightness is automatically adjusted according to the ambient light intensity by the photochromic film, so that the display contrast of the transparent display device is improved, the display content is clearly visible, and outdoor scenes can be seen through. In addition, because the photochromic film does not require electricity, the entire transparent display device also achieves the energy-saving effect.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic structural diagram of a transparent display device according to a first embodiment of the present invention;

FIG. 2 is a schematic structural diagram of a transparent display device according to another first embodiment of the present invention;

FIG. 3 is a schematic structural diagram of a transparent display device according to a second embodiment of the present invention;

FIG. 4 is a schematic structural diagram of a transparent display device according to another second embodiment of the present invention;

FIG. 5 is a schematic structural diagram of a transparent display device according to a third embodiment of the present invention;

FIG. 6 is a schematic structural diagram of a transparent display device according to a fourth embodiment of the present invention; and

FIG. 7 is a schematic structural diagram of a transparent display device according to another fourth embodiment of the present invention.

### DETAILED DESCRIPTION OF PREFERRED EMBODIMENTS

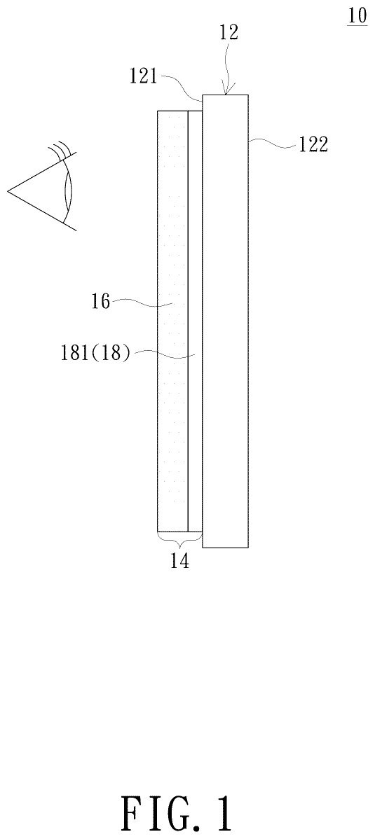

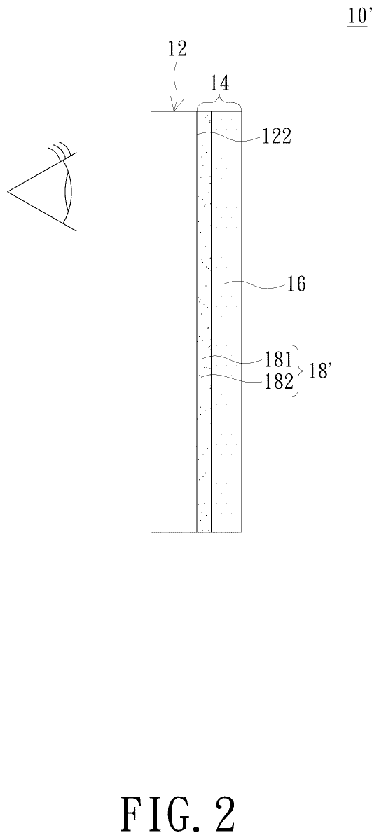

FIG. 1 is a schematic structural diagram of a transparent display device according to a first embodiment of the present invention. As shown in FIG. 1, a transparent display device 10 includes a transparent display module 12 and a photochromic film 14. The transparent display module 12 has a first side 121 and a second side 122 opposite to the first side 121, wherein the first side 121 serves as a display side. The photochromic film 14 is disposed on one of the first side 121 and the second side 122 of the transparent display module 12. The photochromic film 14 includes a photochromic substrate 16 and an adhesive layer 18, and the adhesive layer 18 is disposed on one side of the photochromic substrate 16. In an embodiment, a size of the photochromic film 14 may be less than or equal to a size of the transparent display module 12. In the embodiment shown in FIG. 1, the photochromic film 14 is disposed on the first side 121 of the transparent display module 12, and the size of the photochromic film 14 is, for example, less than the size of the transparent display module 12, which is not limited thereto. FIG. 2 is a schematic structural diagram of a transparent display device according to another first embodiment of the present invention. As shown in FIG. 2, in a transparent display device 10′, a photochromic film 14 is disposed on a second side 122 of a transparent display module 12, and a size of a photochromic film 14 may be equal to a size of the transparent display module 12, which is not limited thereto.

Continuing from the above description, as shown in FIG. 1 or FIG. 2, in an embodiment, the photochromic substrate 16 is suitable for reversibly changing a color when illuminated by an ultraviolet (UV) light source and returning to an original state when the UV light source is removed. The photochromic film 14 is suitable for attachment to the first side 121 of the transparent display module 12 through the adhesive layer 18 (as shown in FIG. 1), or attachment to the second side 122 of the transparent display module 12 (as shown in FIG. 2). In other words, the adhesive layer 18 is disposed between the photochromic substrate 16 and the transparent display module 12. In an embodiment, because the size of the photochromic film 14 may be less than or equal to the size of the transparent display module 12, the transparent display module 12 may be partially attached to the photochromic film 14 (as shown in FIG. 1) or be fully attached to the photochromic film 14 (as shown in FIG. 2).

A material of the photochromic substrate 16 includes polyethylene terephthalate (PET) or polycarbonate (PC), which is not limited thereto. The photochromic substrate 16 further includes but is not limited to a photochromic factor. In an embodiment, a color of the photochromic substrate 16 gradually changes from light to dark as the intensity of an ultraviolet light source increases, so that the photochromic film 14 would automatically adjust the brightness according to the intensity of ambient light (such as the ultraviolet light source). As the intensity of the ultraviolet light source is stronger, the color of the photochromic film 14 is darker. When the intensity of the ultraviolet light source is weak, the color of the photochromic film 14 becomes lighter and may be, for example, approximate to be transparent or colorless. A wavelength of the ambient light ranges from 10 nanometers (nm) to 400 nanometers. Optionally, the wavelength of ambient light ranges from 200 nanometers to 400 nanometers.

In an embodiment, as shown in FIG. 1, the adhesive layer 18 may be, for example, a transparent adhesive 181. Alternatively, as shown in FIG. 2, the adhesive layer 18′ may include, for example, a transparent adhesive 181 and photochromic particles 182, and the photochromic particles 182 are distributed throughout the transparent adhesive 181. In an embodiment, the photochromic particles 182 are suitable for reversibly changing a color when illuminated by an ultraviolet light source and returning to an original state when the UV light source is removed. The adhesive layer 18 or adhesive layer 18′ can be selected according to the user's needs. The use of the adhesive layer 18′ including the photochromic particles 182 in conjunction with the photochromic substrate 16 can have an additive effect on the automatic adjustment of the brightness of the photochromic film 14.

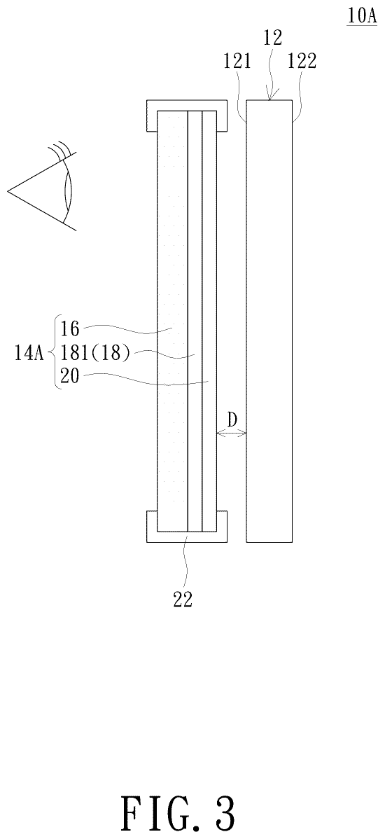

FIG. 3 is a schematic structural diagram of a transparent display device according to a second embodiment of the present invention. As shown in FIG. 3, a transparent display device 10A includes a transparent display module 12 and a photochromic film 14A. The transparent display module 12 has a first side 121 and a second side 122 opposite to the first side 121, wherein the first side 121 serves as a display side. The photochromic film 14A is disposed on one of the first side 121 and the second side 122 of the transparent display module 12. The photochromic film 14A includes a photochromic substrate 16, an adhesive layer 18, and a release film 20. The adhesive layer 18 is disposed on one side of the photochromic substrate 16, and the release film 20 is disposed on one side of the adhesive layer 18 away from the photochromic substrate 16, so that the adhesive layer 18 is disposed between the release film 20 and the photochromic substrate 16.

In the transparent display device 10A of the second embodiment, the photochromic film 14A is not attached to the first side 121 or the second side 122 of the transparent display module 12 as shown in FIG. 1 or FIG. 2, but can be disposed on the first side 121 or the second side 122 of the transparent display module 12 with or without intervals. For example, in FIG. 3, the photochromic film 14A is disposed on the first side 121 of the transparent display module 12, and there is a distance D between the photochromic film 14A and the transparent display module 12, which is not limited thereto. In another embodiment, the photochromic film 14A may be stacked on the first side 121 or the second side 122 of the transparent display module 12 without any intervals.

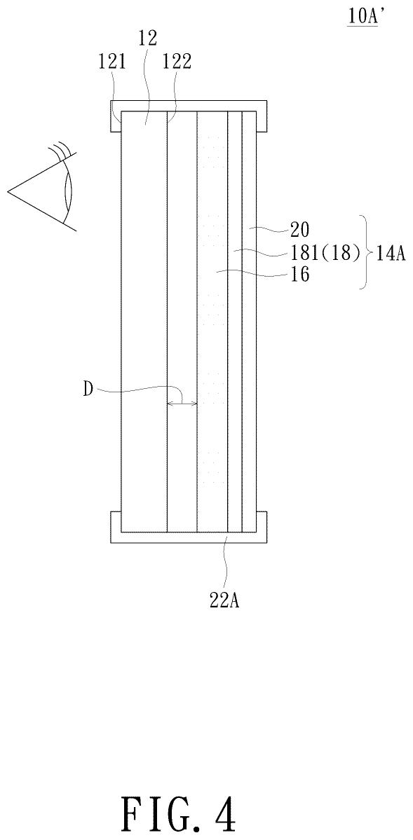

In an embodiment, the transparent display device 10A may further include a frame 22, as shown in FIG. 3. The frame 22 is suitable for framing the release film 20, the adhesive layer 18, and the photochromic substrate 16, the release film 20, the adhesive layer 18, and the photochromic substrate 16 are stacked on each other, so that the photochromic film 14A can be preferably mounted on the first side 121 or the second side 122 of the transparent display module 12 through the frame 22. The design of the frame 22 is not limited thereto. FIG. 4 is a schematic structural diagram of a transparent display device according to another second embodiment of the present invention. As shown in FIG. 4, in a transparent display device 10A′, a frame 22A is not individually framed on a photochromic film 14A, but frames the photochromic film 14A and a transparent display module 12 together. There may be a distance D between the photochromic film 14A and the transparent display module 12, or the photochromic film 14A may be directly stacked on the transparent display module 12. For example, in FIG. 4, there is the distance D between the photochromic film 14A and the second side 122 of the transparent display module 12, and the frame 22A fastens the photochromic film 14A and the transparent display module 12, which is not limited thereto. In an embodiment, the photochromic film 14A may be electrostatically adsorbed onto the transparent display module 12, wherein the photochromic film 14A may be electrostatically adsorbed onto the transparent display module 12, for example, through the release film 20 of the photochromic film 14A, or through the photochromic substrate 16 of the photochromic film 14A. Then the photochromic film 14A and the transparent display module 12 can be framed using the frame 22A for reinforcement.

In the transparent display device 10A/10A′ of the second embodiment, the transparent display module 12 may face the release film 20 of the photochromic film 14A (as shown in FIG. 3), that is, the adhesive layer 18 may be located between the transparent display module 12 and the photochromic substrate 16. Alternatively, the transparent display module 12 may face the photochromic substrate 16 of the photochromic film 14A (as shown in FIG. 4), that is, the photochromic substrate 16 is located between the transparent display module 12 and the adhesive layer 18.

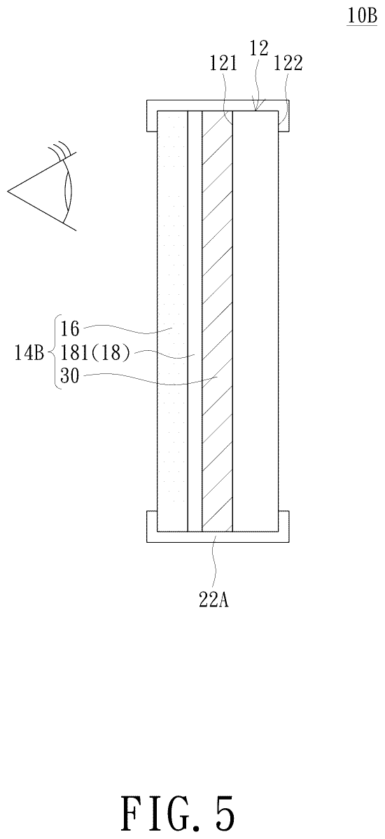

FIG. 5 is a schematic structural diagram of a transparent display device according to a third embodiment of the present invention. As shown in FIG. 5, a transparent display device 10B includes a transparent display module 12 and a photochromic film 14B. The transparent display module 12 has a first side 121 and a second side 122 opposite to the first side 121, wherein the first side 121 serves as a display side. The photochromic film 14B is disposed on one of the first side 121 and the second side 122 of the transparent display module 12. The photochromic film 14B includes a photochromic substrate 16, an adhesive layer 18, and a transparent reinforcing plate 30. The adhesive layer 18 is disposed on one side of the photochromic substrate 16, and the transparent reinforcing plate 30 is disposed on one side of the adhesive layer 18 away from the photochromic substrate 16, so that the adhesive layer 18 is disposed between the transparent reinforcing plate 30 and the photochromic substrate 16. In an embodiment, the transparent reinforcing plate 30 is, for example, transparent glass or transparent acrylic, to enhance a thickness and stiffness of the photochromic film 14B.

In an embodiment not shown, the transparent reinforcing plate 30 may alternatively be disposed in combination with the above photochromic film 14A (that is, a release film 20 is not torn off), and further disposed on one of a first side 121 and a second side 122 of the transparent display module 12. The transparent reinforcing plate 30 may be electrostatically adsorbed onto the photochromic substrate 16 of the photochromic film 14A in order to form a photochromic film structure with the release film 20, the adhesive layer 18, the photochromic substrate 16, and the transparent reinforcing plate 30 that are stacked sequentially. Alternatively, the transparent reinforcing plate 30 may be electrostatically adsorbed onto the release film 20 of the photochromic film 14A in order to form a photochromic film structure with the transparent reinforcing plate 30, the release film 20, the adhesive layer 18, and the photochromic substrate 16 that are stacked sequentially.

Continuing from the above description, the transparent display device 10B may further include the above frame 22 or frame 22A. As shown in FIG. 5, the transparent display device 10B further includes the frame 22A. The photochromic film 14B is directly stacked on the first side 121 of the transparent display module 12, and the photochromic film 14B is fastened to the transparent display module 12 through the frame 22A. In an embodiment not shown, there may be a distance between the photochromic film 14B and the first side 121 of the transparent display module 12. Alternatively, the photochromic film 14B is directly stacked on or disposed at intervals on the second side 122 of the transparent display module 12. In an embodiment not shown, the photochromic film 14B may be framed only by the frame 22, and the photochromic film 14B may be disposed on the first side 121 or the second side 122 of the transparent display module 12 with or without intervals.

In the transparent display device 10B of the third embodiment, as shown in FIG. 5, the transparent display module 12 may face the transparent reinforcing plate 30 of the photochromic film 14B, that is, the adhesive layer 18 may be located between the transparent display module 12 and the photochromic substrate 16. Alternatively, corresponding to the description in FIG. 4, the transparent display module 12 may face the photochromic substrate 16, that is, the photochromic substrate 16 is located between the transparent display module 12 and the adhesive layer 18.

In the above embodiment, the adhesive layer 18 is a transparent adhesive 181 as an example, which is not limited thereto. The adhesive layer 18′ with the photochromic particles 182 (indicated in FIG. 2) may also be used. In the above embodiment, the transparent display module 12 may be, but is not limited to, an organic light-emitting diode display panel. The organic light-emitting diode display panel itself does not need to rely on an additional backlight source. Sub pixels on a screen emit light, and therefore the organic light-emitting diode display panel can remove a backlight layer and keep lightweight.

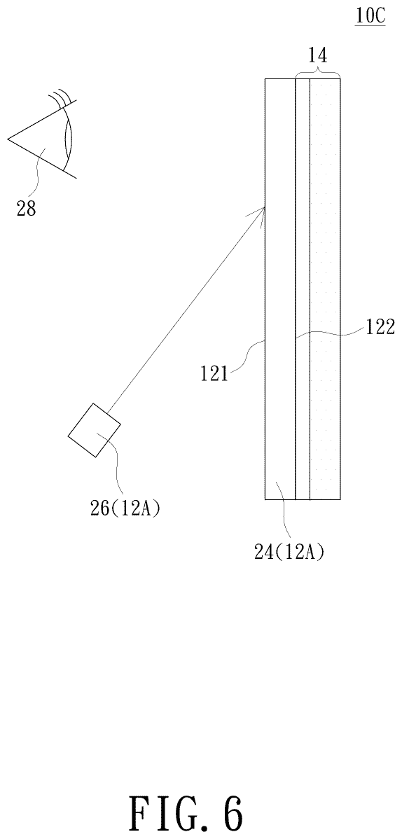

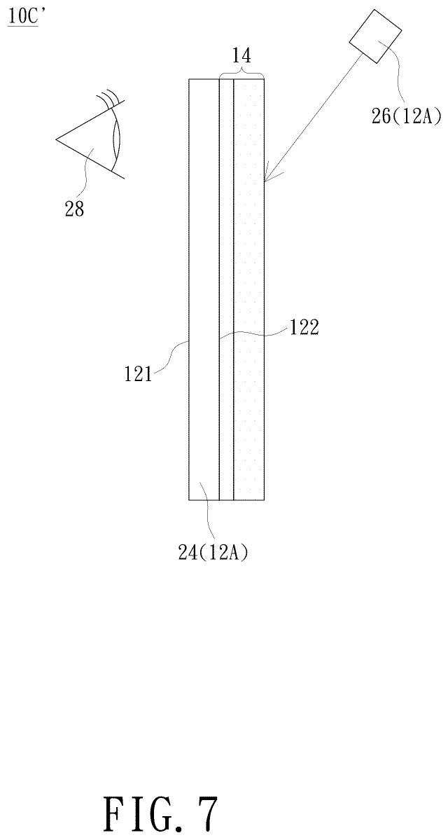

FIG. 6 is a schematic structural diagram of a transparent display device according to a fourth embodiment of the present invention. As shown in FIG. 6, a transparent display device 10C includes a transparent display module 12A and a photochromic film 14. The transparent display module 12A includes a display glass 24 and a projection unit 26. Two opposite sides of the display glass 24 serve as a first side 121 and a second side 122 of the transparent display module 12A, respectively. The projection unit 26 is disposed on one of the first side 121 and the second side 122 and is suitable for projecting an image onto the display glass 24. The projection unit 26 using front projection may be disposed on the first side 121 (that is, a display side), and the projection unit 26 using rear projection may be disposed on the second side 122. For example, in FIG. 6, the projection unit 26 is disposed below the first side 121 (such as on the ground or near the ground), which is not limited thereto. The projection unit 26 may alternatively be disposed above the first side 121 (such as on a ceiling or near a ceiling). FIG. 7 is a schematic structural diagram of a transparent display device according to another fourth embodiment of the present invention. In a transparent display device 10C′, a projection unit 26 is disposed on a second side 122 and is suitable for projecting an image onto the display glass 24. For example, in FIG. 7, the projection unit 26 is disposed above the second side 122 (such as on a ceiling or near a ceiling), which is not limited thereto. The projection unit 26 may alternatively be disposed below the second side 122 (such as on the ground or near the ground).

Continuing from the above description, as shown in FIG. 6 and FIG. 7, in the transparent display device 10C/10C′, for example, the photochromic film 14 is attached to a side (such as the second side 122) of the display glass 24 away from human eyes 28, which is not limited thereto. In an embodiment not shown, the photochromic film 14 may be attached to one side (such as the first side 121) of the display glass 24 adjacent to human eyes 28. Alternatively, the photochromic film 14A (shown in FIG. 3 and FIG. 4) provided with the release film 20, or the photochromic film 14B (shown in FIG. 5) provided with the transparent reinforcing plate 30 may be disposed on the side of the display glass 24 away from the human eyes 28 or on the side of the display glass 24 adjacent to the human eyes 28 with or without intervals.

Based on the above description, in the transparent display device in the embodiments of the present invention, the photochromic film is attached to or disposed on one side of the transparent display module, and the brightness is automatically adjusted according to the ambient light intensity by the photochromic film, so that the display contrast of the transparent display device is improved, the display content is clearly visible, and outdoor scenes can be seen through. Because the photochromic film does not require electricity, the entire transparent display device also achieves the energy-saving effect.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A transparent display device, comprising:
a transparent display module, having a first side and a second side opposite to the first side, wherein the first side serves as a display side; and
a photochromic film, comprising a photochromic substrate and an adhesive layer, wherein the adhesive layer is disposed on one side of the photochromic substrate, and the photochromic film is disposed on one of the first side and the second side of the transparent display module.

2. The transparent display device according to claim 1, wherein the photochromic substrate is suitable for reversibly changing a color when illuminated by an ultraviolet light source and returning to an original state when the ultraviolet light source is removed.

3. The transparent display device according to claim 1, wherein the adhesive layer is disposed between the transparent display module and the photochromic substrate.

4. The transparent display device according to claim 1, wherein the adhesive layer is a transparent adhesive.

5. The transparent display device according to claim 1, wherein the adhesive layer comprises a transparent adhesive and multiple photochromic particles, the photochromic particles are distributed on the transparent adhesive, and the photochromic particles are suitable for reversibly changing a color when illuminated by an ultraviolet light source and returning to an original state when the ultraviolet light source is removed.

6. The transparent display device according to claim 1, wherein the photochromic film further comprises a release film disposed on one side of the adhesive layer away from the photochromic substrate, so that the adhesive layer is disposed between the release film and the photochromic substrate.

7. The transparent display device according to claim 6, wherein the adhesive layer is located between the transparent display module and the photochromic substrate.

8. The transparent display device according to claim 6, wherein the photochromic substrate is located between the transparent display module and the adhesive layer.

9. The transparent display device according to claim 6, further comprising a frame, suitable for framing the release film, the adhesive layer, and the photochromic substrate, and the release film, the adhesive layer, and the photochromic substrate are stacked on each other.

10. The transparent display device according to claim 6, further comprising a frame, suitable for framing the photochromic film and the transparent display module.

11. The transparent display device according to claim 10, wherein the photochromic film is stacked on the transparent display module.

12. The transparent display device according to claim 10, wherein there is a distance between the photochromic film and the transparent display module.

13. The transparent display device according to claim 1, wherein the photochromic film further comprises a transparent reinforcing plate disposed on one side of the adhesive layer away from the photochromic substrate, so that the adhesive layer is disposed between the transparent reinforcing plate and the photochromic substrate.

14. The transparent display device according to claim 13, wherein the adhesive layer is located between the transparent display module and the photochromic substrate.

15. The transparent display device according to claim 13, wherein the photochromic substrate is located between the transparent display module and the adhesive layer.

16. The transparent display device according to claim 13, further comprising a frame, suitable for framing the transparent reinforcing plate, the adhesive layer, and the photochromic substrate, and the transparent reinforcing plate, the adhesive layer, and the photochromic substrate are stacked on each other.

17. The transparent display device according to claim 13, further comprising a frame, suitable for framing the photochromic film and the transparent display module.

18. The transparent display device according to claim 1, wherein a material of the photochromic substrate comprises polyethylene terephthalate (PET) or polycarbonate (PC).

19. The transparent display device according to claim 1, wherein the transparent display module comprises a display glass and a projection unit, two opposite sides of the display glass serve as the first side and the second side respectively, and the projection unit is disposed on one of the first side and the second side and is suitable for projecting an image onto the display glass.

20. The transparent display device according to claim 1, wherein a size of the photochromic film is less than or equal to a size of the transparent display module.
